(19) United States
(12) Patent Application Publication
(10) Pub. No.: US 2023/0053754 A1
(43) Pub. Date: Feb. 23, 2023

(54) LAMINATE, RELEASED LAMINATE, AND METHOD FOR MANUFACTURING RESONATOR

(71) Applicant: SHOWA DENKO K. K., Tokyo (JP)

(72) Inventors: Sho Tonegawa, Ichihara-shi (JP); Akira Sakawaki, Ichihara-shi (JP); Daizo Endo, Ichihara-shi (JP); Kota Hasegawa, Ichihara-shi (JP)

(73) Assignee: SHOWA DENKO K. K., Tokyo (JP)

(21) Appl. No.: 17/587,476

(22) Filed: Jan. 28, 2022

(30) Foreign Application Priority Data
Aug. 20, 2021 (JP) 2021-135111

(51) Int. Cl. H03H 3/02; H03H 9/02; H03H 9/17

(52) U.S. Cl. CPC H03H 3/02; H03H 9/02031; H03H 9/174; H03H 9/176

(57) ABSTRACT

Provided is a laminate including: a substrate 210, an electrode layer 230 disposed on or above the substrate 210 and having a single-crystalline structure containing a metal element; a buffer layer 220 formed between the substrate 210 and the electrode layer 230 and configured to improve crystal orientation of the electrode layer 230; and a piezoelectric layer 240 formed on the electrode layer 230 and made of a piezoelectric body. Each of the buffer layer 220 and the piezoelectric layer 240 has a single-crystalline structure based on a composition of either ScAlN or AlN.

### CROSS REFERENCE TO RELATED APPLICATIONS

This application is based on and claims priority under 35 USC § 119 to Japanese Patent Application No. 2021-135111 filed on Aug. 20, 2021, the disclosure is incorporated herein by reference in its entirety.

### BACKGROUND

### Technical Field

The present invention relates to a laminate, a released laminate, and a method for manufacturing a resonator.

### Related Art

For example, for communications using mobiles phones or smartphones, it is necessary to extract radio waves of desired frequencies using a filter, from among radio waves received at an antenna. One example of such filters is a filter using a resonator. For example, the resonator has a structure in which a piezoelectric layer made of a piezoelectric body is laminated on an electrode.

Previous publications in the art disclose a piezoelectric thin film that includes an aluminum nitride thin film containing scandium, wherein a content of scandium in the aluminum nitride thin film is from 0.5 to 50 atomic %, based on a total of the number of scandium atoms and the number of aluminum atoms being taken as 100 atomic % (see Patent Document 1).

Previous publications in the art also disclose a method for manufacturing a piezoelectric thin film that includes an aluminum nitride thin film containing scandium, the method including a sputtering step of sputtering aluminum and scandium under an atmosphere containing at least a nitrogen gas. The sputtering step of this method performs sputtering at a substrate temperature in a range from 5° C. to 450° C. such that a content of scandium falls within a range from 0.5 to 50 atomic % (see Patent Document 2).

Previous publications in the art also disclose a piezoelectric thin film made of scandium aluminum nitride and obtained by sputtering, wherein a content of carbon atoms is not more than 2.5 atomic %. The method for manufacturing this piezoelectric thin film includes sputtering scandium and aluminum onto a substrate concurrently from a scandium aluminum alloy target material under an atmosphere containing at least a nitrogen gas, the target material having a carbon atomic content of not more than 5 atomic % (see Patent Document 3).

### CITATION LIST

### Patent Literature

Patent Document 1: Japanese Patent Application Laid-Open Publication No. 2009-010926
Patent Document 2: Japanese Patent Application Laid-Open Publication No. 2011-015148
Patent Document 3: Japanese Patent Application Laid-Open Publication No. 2014-236051

### SUMMARY

A recent ever-increasing volume of communications often leads to congestion. To deal with this issue, various advancements have been made including enabling faster communications through higher frequencies and increasing the capacity with wider bandwidths, as well as employing multiple communication bands.

In this case, a high Q value is required for a laminate to prevent interference with an adjacent band and facilitate low-loss characteristics. The laminate is also required to be adapted to a wider bandwidth to meet radio frequency standards. To achieve required characteristics for both of the Q value and the bandwidth, improving crystallinity of the laminate is desired.

It is an object of certain embodiments of the present invention to provide a laminate having high crystallinity, a resonator or a filter using this laminate, and a method for manufacturing this resonator.

Accordingly, certain embodiments of the present invention provide a laminate including: a substrate; an electrode layer disposed on or above the substrate and having a single-crystalline structure containing a metal element; a buffer layer formed between the substrate and the electrode layer and configured to improve crystal orientation of the electrode layer; and a piezoelectric layer formed on the electrode layer and made of a piezoelectric body. Each of the buffer layer and the piezoelectric layer has a single-crystalline structure based on a composition of either ScAlN or AlN.

Peaks at 60 degrees intervals may be observed by X-ray diffraction in a (11-20) plane of the ScAlN and the AlN.

One zone axis may be observed in an electron diffraction pattern of the ScAlN and the AlN.

Both of the buffer layer and the piezoelectric layer may have a same composition.

When the electrode layer is in a cubic crystal system, a lattice mismatch between the electrode layer and the ScAlN or the AlN may be in a range from −25% to 2%.

The electrode layer may have a hexagonal crystal structure.

An X-ray rocking curve full-width at half-maximum (FWHM) of the piezoelectric layer in a (0002) plane may be not more than 2.5°.

When a composition ScₓAl_{y}N (x+y=1), which represents the AlN or the ScAlN, satisfies a relationship of 0≤x≤0.3, the electrode layer may include at least one substance selected from Co, Cu, Ru, Pt, Al, Au, Ag, Mo, W, ZrN, and Ti, and when the composition ScₓAl_{y}N (x+y=1) satisfies a relationship of 0.3<x≤0.5, the electrode layer may include at least one substance selected from Co, Ru, Al, Au, Ag, Mo, W, ZrN, and Ti.

When the ScAlN is represented by a composition ScₓAl_{y}N (x+y=1), a relationship of 0<x≤0.5 may be satisfied.

The substrate may have any composition selected from sapphire, Si, quartz, SrTiO₃, LiTaO₃, LiNbO₃, and SiC.

The electrode layer may have a thickness of from 10 to 1000 nm.

The buffer layer may have a thickness of from 10 to 100 nm.

Certain embodiments of the present invention provide a resonator including a second substrate, a second electrode layer, a piezoelectric layer, and an electrode layer laminated in this order, the piezoelectric layer and the electrode layer being from the above-described laminate, the second substrate being different from the substrate of the laminate, the second electrode layer being different from the electrode layer.

Certain embodiments of the present invention provide a filter including the above-described resonator. The filter is configured to extract radio waves of a required frequency using a piezoelectric layer provided to the resonator.

Certain embodiments of the present invention provide a released laminate obtained by releasing the piezoelectric layer and the electrode layer from the above-described laminate.

Certain embodiments of the present invention provide a method for manufacturing a resonator. The method includes forming a laminate, the laminate including: a substrate; an electrode layer disposed on or above the substrate and having a single-crystalline structure containing a metal element; a buffer layer formed between the substrate and the electrode layer and configured to improve crystal orientation of the electrode layer; and a piezoelectric layer formed on the electrode layer and made of a piezoelectric body. Each of the buffer layer and the piezoelectric layer has a single-crystalline structure based on a composition of either ScAlN or AlN. The method includes forming, on the laminate, a first metal layer containing a metal. The method includes forming, on a surface of a second substrate different from the substrate, a second metal layer containing a metal. The method includes bonding the first metal layer formed on the laminate to the second metal layer on the second substrate. The method includes releasing the substrate and the buffer layer from the laminate.

Releasing the substrate and the buffer layer may include releasing both of the substrate and the buffer layer at a time.

Releasing the substrate and the buffer layer may include releasing the substrate and then releasing the buffer layer.

Certain embodiments of the present invention can provide a laminate having high crystallinity, a resonator or a filter using this laminate, and a method for manufacturing this resonator.

### BRIEF DESCRIPTION OF THE DRAWINGS

Exemplary embodiments of the present invention will be described in detail based on the following figures, wherein:

FIG. 1 shows a resonator according to an embodiment;

FIG. 2 shows a laminate used to fabricate a piezoelectric layer;

FIG. 3 shows relationship between combinations of the piezoelectric layer, an electrode layer, a buffer layer, and a substrate and crystallinity of the piezoelectric layer;

FIG. 4A shows a transmission electron microscope (TEM) image of AlN according to the embodiment;

FIG. 4B shows an electron diffraction pattern of AlN according to the embodiment;

FIG. 4C shows a TEM image of Sc_{0.2}Al_{0.8}N according to the embodiment;

FIG. 4D shows an electron diffraction pattern of Sc_{0.2}Al_{0.8}N according to the embodiment;

FIG. 4E shows a TEM image of polycrystalline AlN;

FIG. 4F shows an electron diffraction pattern of polycrystalline AlN;

FIG. 5 shows a result of in-plane X-ray diffraction when Sc_{0.2}Al_{0.8}N according to the embodiment has a small FWHM;

FIGS. 6A-6E each show an interatomic distance x used to calculate a lattice mismatch;

FIG. 7 is a table showing specific examples of lattice mismatches between the electrode layer and the piezoelectric layer;

FIG. 8 is a flowchart of a method for manufacturing the laminate;

FIG. 9 shows the buffer layer, the electrode layer, and the piezoelectric layer deposited; and

FIGS. 10A-10F show a method for manufacturing the resonator.

### DETAILED DESCRIPTION

An embodiment of the present invention will be described below with reference to the attached drawings.

### Overall Description of a Resonator 100

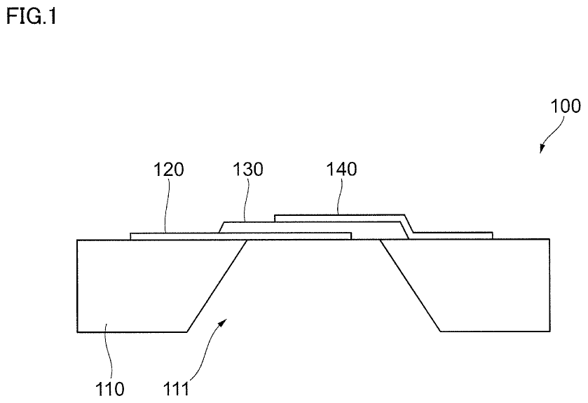

FIG. 1 shows a resonator 100 according to an embodiment.

The resonator 100 as shown includes a substrate 110 as a support body, a lower electrode layer 120 as an electrode formed on a lower side, a piezoelectric layer 130 made of a piezoelectric body, and an upper electrode layer 140 as an electrode formed on an upper side. The substrate 110, the lower electrode layer 120, the piezoelectric layer 130, and the upper electrode layer 140 are laminated in this order from bottom to top. It should be noted that any terms of orientation such as “lower,” “upper,” “top,” and “bottom” are used to indicate orientations of these layers in the figures for purposes of conveniently illustrating how they are laminated. As such, these layers are not necessarily oriented as shown when the resonator 100 is actually used.

The substrate 110 is a support substrate to support the lower electrode layer 120, the piezoelectric layer 130, and the upper electrode layer 140. The substrate 110 is an example of the second substrate. This support substrate is different from a substrate for the growing of a thin film of the piezoelectric layer 130. In the present embodiment, for example, a single-crystalline silicon (Si) substrate is used for the substrate 110. The substrate 110 includes a cavity 111 in its lower portion.

The lower electrode layer 120, which is an example of the second electrode layer, is formed on the substrate 110. The material of the lower electrode layer 120 is not particularly limited; for example, the lower electrode layer 120 may be made of ruthenium (Ru), gold (Au), silver (Ag), copper (Cu), platinum (Pt), aluminum (Al), molybdenum (Mo), tungsten (W), and the like.

The piezoelectric layer 130 is formed on the lower electrode layer 120 and made of a piezoelectric body. As will be detailed in subsequent paragraphs, radio waves of desired frequencies are selectively extracted using a piezoelectric effect provided by the piezoelectric body.

The upper electrode layer 140, which is an example of the electrode layer, is formed on the piezoelectric layer 130. The upper electrode layer 140 has a single-crystalline structure containing a metal element. The upper electrode layer 140 may be made of the same metal as that of the lower electrode layer 120, or may be made of a different metal from that of the lower electrode layer 120.

That is, the resonator 100 has a structure in which the piezoelectric layer 130 is sandwiched between the lower electrode layer 120 and the upper electrode layer 140. For example, the lower electrode layer 120, the piezoelectric layer 130, and the upper electrode layer 140 may be formed by sputtering.

For example, the resonator 100 may be used for a bandpass filter (BPF). In particular, the resonator 100 is preferably used for a bulk acoustic wave (BAW) filter. The resonator 100 as shown in FIG. 1 is a BAW filter of a film bulk acoustic resonator (FBAR) type. The FBAR-type BAW filter includes the cavity 111 in a lower portion of the resonator. This allows the piezoelectric layer 130 to freely vibrate without being constrained by the substrate 110. Additionally, this allows for making the piezoelectric layer 130 thin by sputtering or other means, and also eliminates the need for providing an electrode in a fine pattern, which would be required in the case of a surface acoustic wave (SAW) filter using surface acoustic waves. Thus, the resonator 100 has characteristics that facilitate operation at high frequencies.

The BAW is an elastic wave that propagates in a medium having a three-dimensional extension. In this case, the BAW propagates in the piezoelectric layer 130 as a medium while performing longitudinal vibration in the thickness direction of the piezoelectric layer 130. The elastic wave causes the piezoelectric layer 130 to resonate. In this case, an input radio wave causes the piezoelectric layer 130 to resonate. The range of frequencies that resonate the piezoelectric layer 130 corresponds to the range of frequencies of radio waves that are intended to be extracted from input radio waves. This range of frequencies can be adjusted by varying the thickness, composition, and other characteristics of the piezoelectric layer 130.

Once vibrations occur by resonance, the vibrations are converted by the piezoelectric layer 130 into electric signals. In other words, by utilizing the resonance of the piezoelectric layer 130, radio waves within a predetermined frequency range can be extracted and converted into electric signals.

When the resonator 100 is used as a high-frequency bandpass filter, it is required to ensure both a high Q value and a wide bandwidth. The Q value is a quality factor, representing sharpness of selectable frequencies. A high Q value corresponds to excellent steepness for preventing interference with adjacent frequency bands, as well as excellent low-loss characteristics. The bandwidth is a width of selectable frequencies, which is defined as a difference between highest and lowest frequencies of radio waves that can pass through the bandpass filter. Covering a wide bandwidth further facilitates meeting frequency standards of devices that use the filter. The bandwidth is proportional to an electromechanical coupling coefficient k² of the piezoelectric body constituting the piezoelectric layer 130. The electromechanical coupling coefficient k² is a quantity that represents the efficiency of the piezoelectric effect. A higher Q value and a higher electromechanical coupling coefficient k² are preferred.

The product of the above two parameters, namely k²Q can be viewed as a performance index of the bandpass filter. The value of k²Q depends on the characteristics of the piezoelectric body constituting the piezoelectric layer 130. Some previous approaches have attempted to use, for example, AlN or ScAlN for the piezoelectric body. However, AlN as used in previous approaches is unable to cover a sufficient bandwidth. Also, ScAlN as used in previous approaches increases the bandwidth but reduces the Q value. That is, it difficult to ensure both a wide bandwidth and a high Q value in previous approaches.

The piezoelectric layer 130 of the present embodiment is single-crystalline. By virtue of the piezoelectric layer 130 being single-crystalline, one can expect to obtain a wide bandwidth as well as a high Q value by using the resonator 100 as a bandpass filter. In other words, it can be expected that both a high Q value and a wide bandwidth are ensured.

### Laminate for Fabricating the Piezoelectric Layer 130

Now a description will be given of a laminate for fabricating the single-crystalline piezoelectric layer 130.

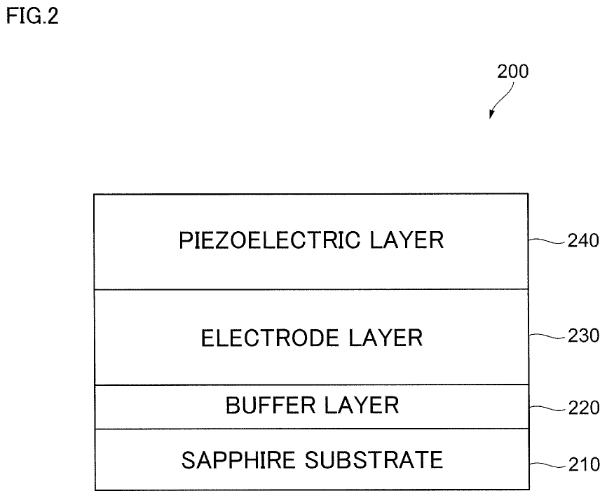

FIG. 2 shows a laminate 200 used to fabricate the piezoelectric layer 130.

The laminate 200 as shown includes a substrate 210, a buffer layer 220 as an intermediate layer, an electrode layer 230 serving as an electrode, and a piezoelectric layer 240 made of a piezoelectric body.

The substrate 210 is a growth substrate on which the buffer layer 220, the electrode layer 230, and the piezoelectric layer 240 are grown as thin films by sputtering. For this reason, a single-crystalline substrate is used for the substrate 210.

The buffer layer 220 is an intermediate layer formed between the substrate 210 and the electrode layer 230 to improve the crystal orientation of the electrode layer 230.

The electrode layer 230 corresponds to the upper electrode layer 140 in the resonator 100 of FIG. 1. Thus, the electrode layer 230 has a single-crystalline structure containing a metal element.

The piezoelectric layer 240 corresponds to the piezoelectric layer 130 in the resonator 100 of FIG. 1. Thus, the piezoelectric layer 240 is made of a piezoelectric body.

In the present embodiment, the buffer layer 220 and the piezoelectric layer 240 are AlN-based single-crystalline layers. The term “AlN-based” or “based on AlN” means containing AlN at a molar ratio of 50% or more. The buffer layer 220 and the piezoelectric layer 240 may be ScAlN-based single-crystalline layers, instead of being AlN-based single-crystalline layers. The buffer layer 220, the electrode layer 230, and the piezoelectric layer 240 are detailed in subsequent paragraphs.

In the present embodiment, the buffer layer 220 and the piezoelectric layer 240 are single-crystalline layers based on a composition of either ScAlN or AlN. ScAlN can be viewed as a composition that is obtained by substituting Al in AlN with Sc. Thus, ScAlN can also be denoted as ScₓAl_{y}N (x+y=1), where x is preferably from 0 to 0.5, and y is preferably from 0.5 to 1.0. If x is more than 0.5, it would change the crystal system of ScAlN and degrade the piezoelectricity. In the context of increasing the crystallinity, x is preferably from 0.005 to 0.35, and y is more preferably from 0.65 to 0.995. In the context of increasing the piezoelectricity of the piezoelectric layer 240, x is preferably from 0.35 to 0.5, and y is preferably from 0.5 to 0.65. In practice, the values of x and y are determined as appropriate in the context of the crystallinity that can satisfy the required characteristics for the piezoelectric layer 240 and the required piezoelectricity for the piezoelectric layer 240. In the present embodiment, ScAlN having a composition of Sc_{0.2}Al_{0.8}N is mainly used.

The electrode layer 230 is based on single-crystalline Ru as described above. As will be detailed in subsequent paragraphs, the buffer layer 220, the electrode layer 230, and the piezoelectric layer 240 can be formed by sputtering, for example. Employing the above material combination for the buffer layer 220, the electrode layer 230, and the piezoelectric layer 240 facilitates making each layer single-crystalline.

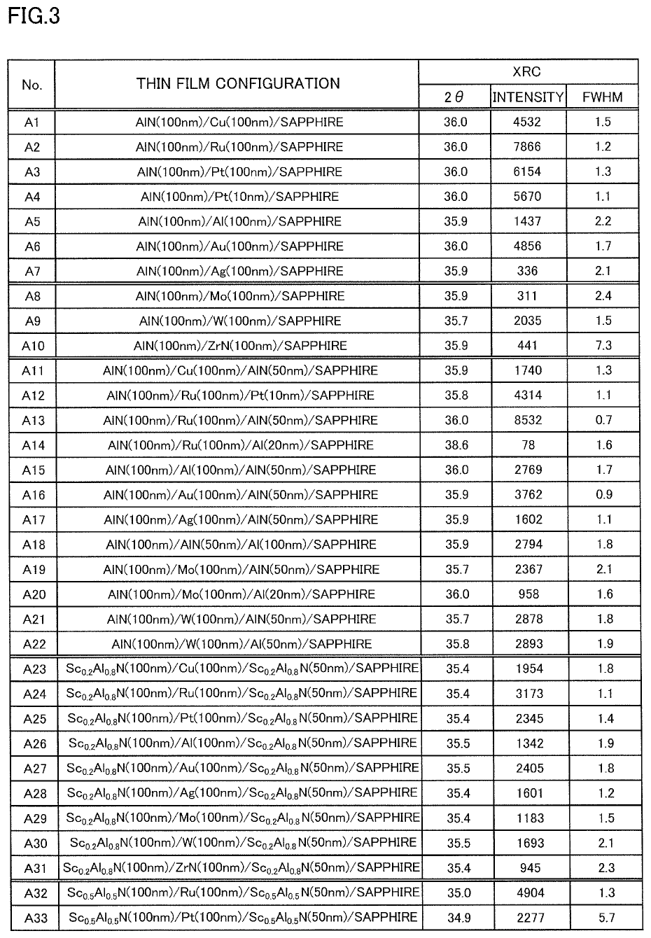

FIG. 3 shows relationship between combinations of the piezoelectric layer 240, the electrode layer 230, the buffer layer 220, and the substrate 210 and crystallinity of the piezoelectric layer.

The figure shows thin film configurations fabricated and results of X-ray rocking curve (XRC) measurement. The thin film configurations represent combinations of layers constituting the thin film, with values in parentheses representing thickness of each layer. The XRC results include three parameters, namely 20, intensity, and full-width at half-maximum (FWHM) of the (0002) plane of the piezoelectric layer 240.

In FIG. 3, Nos. A1 to A10 correspond to XRC results for combinations of the piezoelectric layer 240/the electrode layer 230/the substrate 210. In other words, the buffer layer 220 is not formed in these examples.

In these examples, AlN is used for the piezoelectric layer 240. Also, Cu, Ru, Pt, Al, Au, Ag, Mo, W, or ZrN is used for the electrode layer 230. The substrate 210 is made of sapphire.

The figure shows that all of these examples except for No. A10 produce a small FWHM and allow for forming the piezoelectric layer 240 with good crystallinity. In other words, this demonstrates that it is effective to use a metal for the electrode layer 230. On the other hand, in the case of not using any metal for the electrode layer 230 as in No. A10, the FWHM is large, which indicates that the piezoelectric layer 240 with good crystallinity is not formed above the sapphire substrate 210.

In FIG. 3, Nos. A11 to A22 correspond to XRC results for combinations of the piezoelectric layer 240/the electrode layer 230/the buffer layer 220/the substrate 210. It should be noted that these examples include a case where the electrode layer 230 and the buffer layer 220 are interchanged, as in No. A18.

In these examples, AlN is used for the piezoelectric layer 240. Also, Cu, Ru, Al, Au, Ag, Mo, or W is used for the electrode layer 230. Further, AlN, Pt, or Al is used for the buffer layer 220. The substrate 210 is made of sapphire.

The figure shows that all of these examples produce a small FWHM and allow for forming the piezoelectric layer 240 with good crystallinity. This demonstrates that using AlN for the piezoelectric layer 240 and the buffer layer 220 and using a metal for the electrode layer 230 allow for forming the piezoelectric layer 240 with good crystallinity.

In FIG. 3, Nos. A23 to A31 correspond to XRC results for cases when Sc_{0.2}Al_{0.8}N is used for the piezoelectric layer 240 and the buffer layer 220.

The figure shows that all of these examples produce a small FWHM and allow for forming the piezoelectric layer 240 with good crystallinity. This demonstrates that using Sc_{0.2}Al_{0.8}N for the piezoelectric layer 240 and the buffer layer 220 and using a metal for the electrode layer 230 allow for forming the piezoelectric layer 240 with good crystallinity.

In FIG. 3, Nos. A32 and A33 correspond to XRC results for cases when Sc_{0.5}Al_{0.5}N is used for the piezoelectric layer 240.

The figure shows that the example No. A32 produces a small FWHM and allows for forming the piezoelectric layer 240 with good crystallinity. On the other hand, the example No. A33 produces a large FWHM.

As indicated from the comparisons between A1 and A11, A2 and A13, A5 and A15, etc., providing the buffer layer 220 between the substrate 210 and the electrode layer 230 improves the crystallinity of the piezoelectric layer 240.

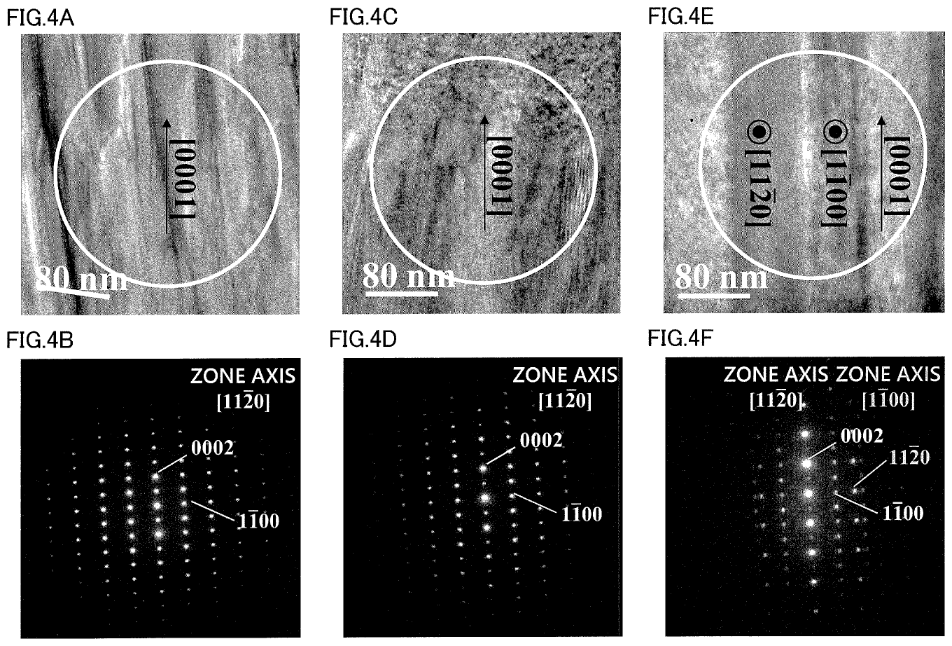

FIG. 4A shows a transmission electron microscope (TEM) image of AlN according to the present embodiment. The upward direction in the figure corresponds to the crystal growth direction, and AlN has the [0001]crystallographic axis.

FIG. 4B shows an electron diffraction pattern of AlN according to the present embodiment. The electron diffraction pattern shown in FIG. 4B was obtained by electron beam irradiation of a portion within the circle of FIG. 4A. The diameter of the electron beam as represented by this circle is about 200 nm.

As shown in FIG. 4B, in terms of the Miller indices, the (0002) plane and the (1-100) plane are observed in AlN according to the present embodiment. In this case, only the zone axis [11-20] is present. In other words, only one zone axis is observed as the electron diffraction pattern. This means that AlN according to the present embodiment is a single crystal substance with excellent crystallinity. Also, this AlN according to the present embodiment can be said to have a triaxial orientation as it is c-axis oriented with the ab in-plane rotations controlled. In this case, the AlN consists of columnar domains of a single kind extending in the c-axis direction with rotational directions aligned in the ab plane.

It should be noted that although negative values are usually written with a bar above the number in the Miller index notation and the zone axis notation as shown in the figures, negative values are herein denoted with a negative sign (−) for convenience of description.

FIG. 4C shows a TEM image of Sc_{0.2}Al_{0.8}N according to the present embodiment. As with the above example, the upward direction in the figure corresponds to the crystal growth direction, and Sc_{0.2}Al_{0.8}N has the crystallographic axis.

FIG. 4D shows an electron diffraction pattern of Sc_{0.2}Al_{0.8}N according to the present embodiment. As shown in FIG. 4D, in terms of the Miller indices, the (0002) plane and the (1-100) plane are observed in Sc_{0.2}Al_{0.8}N according to the present embodiment. In this case, only the [11-20] zone axis is present. In other words, in this case too, only one zone axis is observed as the electron diffraction pattern. This means that Sc_{0.2}Al_{0.8}N according to the present embodiment is a single crystal substance with excellent crystallinity. In other words, Sc_{0.2}Al_{0.8}N according to the present embodiment can be said to also have a triaxial orientation. In this case, Sc_{0.2}Al_{0.8}N consists of columnar domains of a single kind extending in the c-axis direction with rotational directions aligned in the ab plane.

FIG. 4E shows a TEM image of polycrystalline AlN. As with the above examples, the upward direction in the figure corresponds to the crystal growth direction, and AlN has the crystallographic axis.

FIG. 4F shows an electron diffraction pattern of polycrystalline AlN. As shown in FIG. 4F, in terms of the Miller indices, the (11-20) plane in addition to the (0002) plane and the (1-100) plane are observed in polycrystalline AlN. In this case, two zone axes of [11-20] and [1-100] are present. That is, in this case, two zone axes are observed as the electron diffraction pattern. This demonstrates that this AlN is polycrystalline. FIG. 4E shows portions where the [11-20] and [1-100] zone axes are observed.

That is, this AlN is c-axis oriented but does not have the ab in-plane rotations controlled. In this case, the AlN consists of columnar domains of two different kinds rotated by 300 with respect to each other in the ab plane and extending in the c-axis direction.

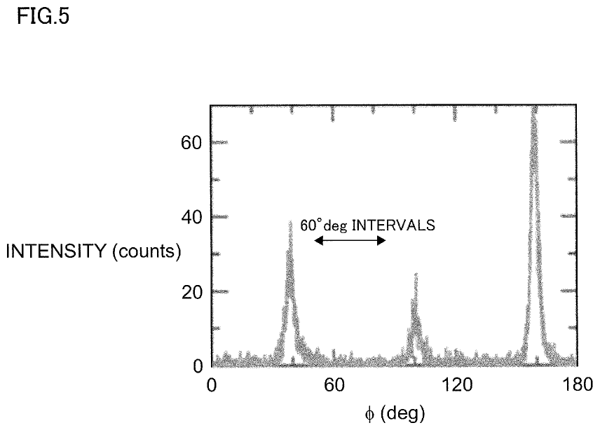

FIG. 5 shows a result of in-plane X-ray diffraction when Sc_{0.2}Al_{0.8}N according to the present embodiment has a small FWHM. That is, FIG. 5 shows a result of in-plane X-ray diffraction in the case of FIG. 4C.

The in-plane X-ray diffraction is also referred to as in-plane XRD, which can be used to evaluate the crystallinity of Sc_{0.2}Al_{0.8}N. The Miller index of this measured plane of Sc_{0.2}Al_{0.8}N is (11-20). That is, this plane is perpendicular to the surface of the Sc_{0.2}Al_{0.8}N layer. As shown, peeks at 60 degrees intervals appear in the in-plane X-ray diffraction pattern. This demonstrates that the plane of Sc_{0.2}Al_{0.8}N according to the present embodiment has a six-fold symmetry structure and is single-crystalline with good crystallinity. It should be noted that these peeks at 60 degrees intervals also appear in the in-plane X-ray diffraction pattern of AlN shown in FIG. 4A.

### Electrode Layer 230

Metals that can be used for the electrode layer 230 are required to ensure that the piezoelectric layer 240 with excellent crystallinity can be formed on the electrode layer 230. Since AlN or ScAlN constituting the piezoelectric layer 240 is hexagonal system, any hexagonal system metal, when used for the electrode layer 230, will ensure that the piezoelectric layer 240 with excellent crystallinity can be formed on the electrode layer 230. For example, when sputtering is used to form the piezoelectric layer 240 on the electrode layer 230, the hexagonal AlN (0001) plane or ScAlN (0001) plane epitaxially grow on the (0001) plane of the metal that is hexagonal system as well. That is, the growth plane of AlN and ScAlN is the (0001) plane. Put other ways, the growth plane of AlN and ScAlN is the c-plane, and they grow in the c-axis direction.

In the case of using any cubic system metal, on the other hand, a difference in lattice constants between the electrode layer 230 and the piezoelectric layer 240 can be problematic. In this case, it is required that a lattice mismatch between the electrode layer 230 and ScAlN or AlN constituting the piezoelectric layer 240 be in a range from −25% to 2%. In this case, the hexagonal AlN (0001) plane or ScAlN (0001) plane grow on the fcc (111) plane or the bcc (110) plane of the cubic system metal.

A lattice mismatch can be expressed as Δx/x, which represents a ratio of a difference Δx between interatomic distances of the electrode layer 230 and the piezoelectric layer 240 to the interatomic distance x of the electrode layer 230. When this value is small, the piezoelectric layer 240 can be formed on the electrode layer 230 even with the presence of a lattice mismatch. For example, when sputtering is used to form the piezoelectric layer 240 on the electrode layer 230, the thin film of the piezoelectric layer 240 can be epitaxially grown on the electrode layer 230. In this case, the crystal lattice of AlN or ScAlN constituting the piezoelectric layer 240 is distorted on the electrode layer 230, which causes the piezoelectric layer 240 to epitaxially grow while preserving lattice continuity at the interface between these layers.

The lattice mismatch may be a simple ratio of the lattice constants of the electrode layer 230 and the piezoelectric layer 240 when both of them have a hexagonal crystal structure. When, on the other hand, the electrode layer 230 has a cubic crystal structure and the piezoelectric layer 240 has a hexagonal crystal structure, a three-dimensional view should be taken.

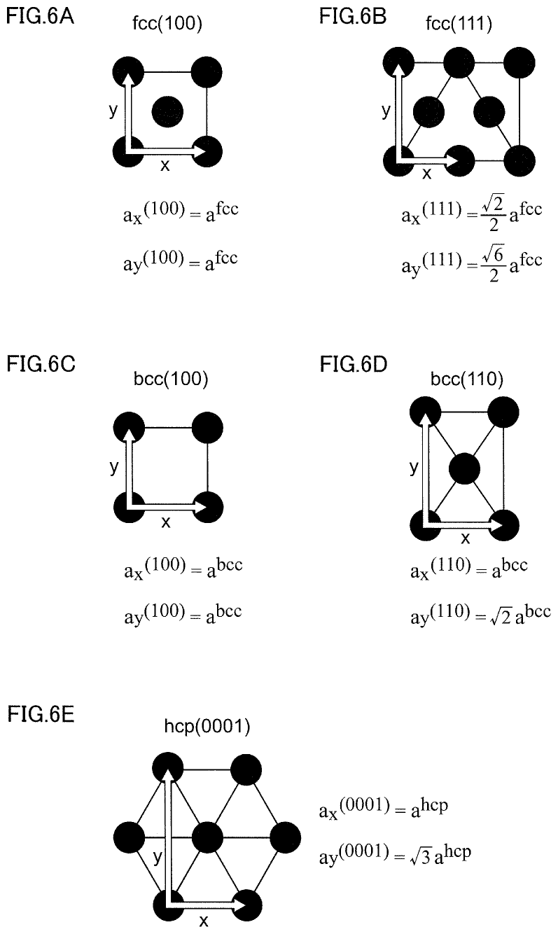

FIGS. 6A-6E each show the interatomic distance x used to calculate the lattice mismatch.

FIG. 6A shows a cubic fcc (100) plane ((100) plane of the face-centered cubic lattice), and FIG. 6B shows a cubic fcc (111) plane. In the case of FIG. 6A, based on the lattice constant being a^{fcc}, x is aₓ⁽¹⁰⁰⁾=a^{fcc}, so that the lattice constant a^{fcc} can be directly used. In the case of FIG. 6B, on the other hand, based on the lattice constant being a^{fcc}, x is aₓ⁽¹¹¹⁾=(√2/2)a^{fcc}, so that the lattice constant a^{fcc} cannot be directly used. Thus, when the hexagonal AlN (0001) plane or ScAlN (0001) plane is to be grown on the fcc (111) plane of a cubic metal, the lattice constant a^{fcc} cannot be directly used, and (√2/2)a^{fcc} is used as the interatomic distance x.

FIG. 6C shows a cubic bcc (100) plane ((100) plane of the body-centered cubic lattice), and FIG. 6D shows a cubic bcc (110) plane. In the case of FIG. 6C, based on the lattice constant being a^{bcc}, x is aₓ⁽¹⁰⁰⁾=a^{bcc}, so that the lattice constant a^{bcc} can be directly used. In the case of FIG. 6D, based on the lattice constant being a^{bcc}, x is aₓ⁽¹¹⁰⁾=a^{bcc}, so that the lattice constant a^{bcc} can be directly used too. Thus, when the hexagonal AlN (0001) plane or ScAlN (0001) plane is to be grown on the bcc (110) plane of a cubic metal, the lattice constant a^{bcc} can be directly used as the interatomic distance x.

FIG. 6E shows a hexagonal (0001) plane. In the case of FIG. 6E, based on the lattice constant being a^{hcp}, x (=aₓ⁽⁰⁰⁰¹⁾) is aₓ⁽⁰⁰⁰¹⁾=a^{hcp}, so that the lattice constant a^{hcp} can be directly used. Thus, when the hexagonal AlN (0001) plane or ScAlN (0001) plane is to be grown on the (0001) plane of a hexagonal metal, the lattice constant a^{hcp} can be directly used as the interatomic distance x.

However, in actual crystal systems, an interatomic distance y is also present as shown in each of FIGS. 6A to 6E. In one example, in the case of the cubic bcc (110) plane shown in FIG. 6D, y=√2x. In another example, in the case of the hexagonal (0001) plane shown in FIG. 6E, y=√3x. Thus, during the actual epitaxial growth, x values match, but y values do not match, so that the lattice distortion is occurring.

That is, the interatomic distance x refers to a distance between the closest atoms in the respective planes of the electrode layer 230 and the piezoelectric layer 240 at which they adjoin each other.

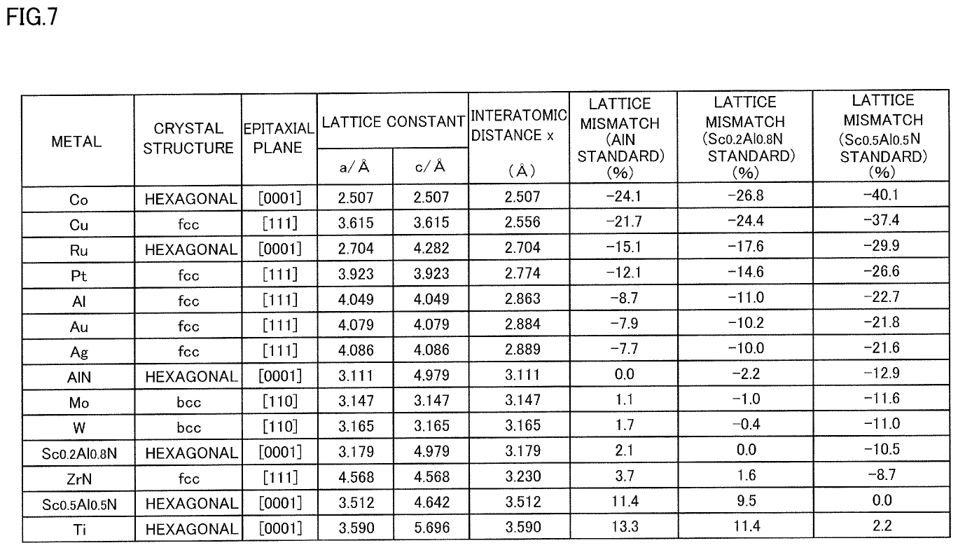

FIG. 7 is a table showing specific examples of lattice mismatches between the electrode layer 230 and the piezoelectric layer 240.

FIG. 7 lists the kinds of materials (denoted as “metal”) constituting the electrode layer 230, their crystal structures, epitaxial growth planes (denoted as “epitaxial plane”), lattice constants, interatomic distances x, and lattice mismatches. As regards the crystal structures, “fcc” and “bcc” represent cubic system, and “hexagonal” represents hexagonal system. The table shows three different lattice mismatches, namely with respect to AlN, Sc_{0.2}Al_{0.8}N, and Sc_{0.5}Al_{0.5}N. The table also lists AlN, Sc_{0.2}Al_{0.8}N, Sc_{0.5}Al_{0.5}N, and ZrN, as well as metals. Preferably, the material constituting the electrode layer 230 is chosen from those that ensure that an FWHM of an X-ray rocking curve (XRC) of the (0002) plane of the piezoelectric layer 240, as shown in FIG. 3, is not more than 2.5°. In other words, an XRC FWHM of not more than 2.5° will provide excellent crystallinity, but an XRC FWHM of more than 2.5° will not provide excellent crystallinity.

In this context, when the composition ScₓAl_{y}N (x+y=1) representing AlN or ScAlN satisfies 0≤x≤0.3, it is preferred that the material constituting the electrode layer 230 include at least one substance selected from Co, Cu, Ru, Pt, Al, Au, Ag, Mo, W, ZrN, and Ti. Also, when the composition ScₓAl_{y}N (x+y=1) representing AlN or ScAlN satisfies 0.3<x≤0.5, it is preferred that the material constituting the electrode layer 230 include at least one substance selected from Co, Ru, Al, Au, Ag, Mo, W, ZrN, and Ti. These may be used alone, or alloys thereof may also be used.

### Substrate 210

In the above example, sapphire is used for the substrate 210, but this is not limiting. Nevertheless, it is preferred that use be made of a substrate that has any composition selected from sapphire, Si, quartz, SrTiO₃, LiTaO₃, LiNbO₃, and SiC. The substrate 210 with such a composition further facilitates epitaxial growth thereon of the buffer layer 220 made of AlN or ScAlN.

### Description of a Method for Manufacturing the Laminate 200

Now a description will be given of a method for manufacturing the laminate 200.

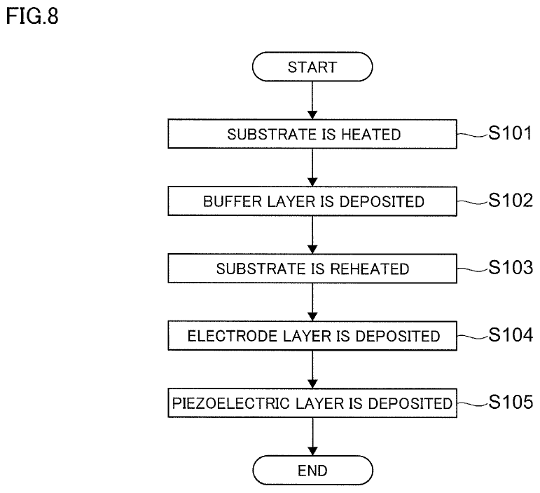

FIG. 8 is a flowchart of a method for manufacturing the laminate 200.

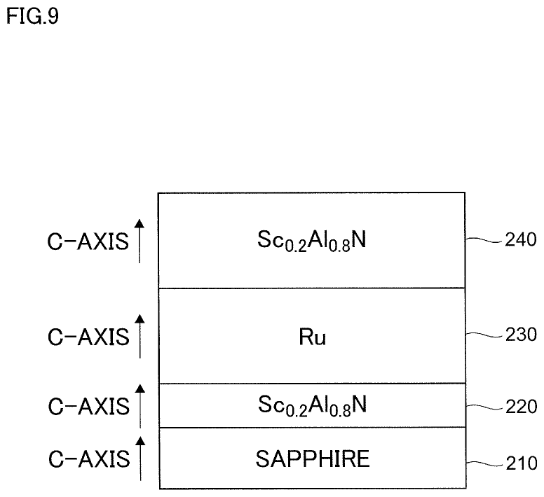

FIG. 9 shows the buffer layer 220, the electrode layer 230, and the piezoelectric layer 240 deposited on the substrate 210 in this method.

First, the substrate 210, which is a single-crystalline sapphire substrate and has a c-plane surface, is loaded into the sputtering apparatus and heated to have moisture removed therefrom (step 101). For example, the substrate 210 is heated twice each for 30 seconds at 1000 W. During heating, the temperature of the substrate 210 reaches about 400 to 500° C.

Then, a thin film of Sc_{0.2}Al_{0.8}N is deposited as the buffer layer 220 on the substrate 210 (step 102). In the present embodiment, the Hi-pulse sputtering method is used to deposit the buffer layer 220. The Hi-pulse sputtering method applies a voltage between the substrate 210 and a target in pulses. The method generates plasma from a sputtering gas introduced into the sputtering apparatus and causes it to collide with the target to thereby deposit components dislodged from the target onto the substrate 210 and form a film thereon. In this case, the target is Al containing 20% Sc, and a gas mixture of argon (Ar) and nitrogen (N₂) at a ratio of 1:1 is used as the sputtering gas. Also, a sputtering gas pressure is set to 0.73 Pa. A voltage between the substrate 210 and the target is set to 929 V, and an electric current is set to 2.5 A. As regards pulse conditions, a pulse width is set to 20 μs at 1000 Hz. That is, the duty ratio under these conditions is 2%. Components dislodged from the target react with nitrogen in a plasma state to produce Sc_{0.2}Al_{0.8}N. Preferably, the buffer layer 220 has a thickness of from 10 nm to 100 nm. If the buffer layer 220 has a thickness of less than 10 nm, island growth would occur, making it impossible to well cover the surface. On the other hand, if the buffer layer 220 has a thickness of more than 100 nm, dislocations or defects would be likely to occur.

Since Al containing 20% Sc is used as the target, the film of Sc_{0.2}Al_{0.8}N is deposited. Varying the ratio of Sc and Al in the target can vary the ratio of Sc and Al in the ScAlN film deposited.

Then, the substrate 210 with the buffer layer 220 deposited thereon is reheated (step 103). For example, the substrate 210 is heated once for 30 seconds at 1000 W. During heating, the temperature of the substrate 210 reaches about 400 to 500° C. This improves crystallinity of the electrode layer 230 during the subsequent formation of the electrode layer 230.

Then, a thin film of Ru is deposited as the electrode layer 230 on the buffer layer 220 (step 104). At this time, in the present embodiment, a normal DC sputtering method is used, rather than the Hi-pulse sputtering method. A target made of Ru is used, and Ar is used for a sputtering gas. Pressure of the sputtering gas is set to, for example, 0.5 Pa, and the sputtering is conducted at 1000 W. Preferably, the electrode layer 230 has a thickness of from 10 nm to 1000 nm. If the electrode layer 230 has a thickness of less than 10 nm, the electrode layer 230 might not function well as an electrode. On the other hand, if the electrode layer 230 has a thickness of more than 1000 nm, it has almost the same thickness as the piezoelectric layer, which may adversely affect the piezoelectricity.

Further, a thin film of Sc_{0.2}Al_{0.8}N is deposited as the piezoelectric layer 240 on the electrode layer 230 (step 105). At this time, in the present embodiment, the Hi-pulse sputtering method is used to deposit the piezoelectric layer 240 using the target containing Al and Sc. The sputtering conditions are the same as those at step 102, but the deposition takes several hours. At this time, the temperature of the substrate 210 settles at about 200 to 350° C. The piezoelectric layer 240 is formed on the entire surface of the electrode layer 230. Preferably, the piezoelectric layer 240 has a thickness of from 10 nm to 5000 nm.

In the above example, both of the buffer layer 220 and the piezoelectric layer 240 are made of Sc_{0.2}Al_{0.8}N. Alternatively, both of the buffer layer 220 and the piezoelectric layer 240 may be made of AlN. That is, preferably, both of the buffer layer 220 and the piezoelectric layer 240 are made of ScAlN or AlN. In other words, preferably, the buffer layer 220 and the piezoelectric layer 240 have the same composition. This eliminates the need for replacing the target. Alternatively, one of the buffer layer 220 and the piezoelectric layer 240 may be made of ScAlN and the other may be made of AlN. This, however, requires replacement of the target.

### Description of a Method for Manufacturing the Resonator 100

Now a description will be given of a method for manufacturing the resonator 100 using the laminate 200.

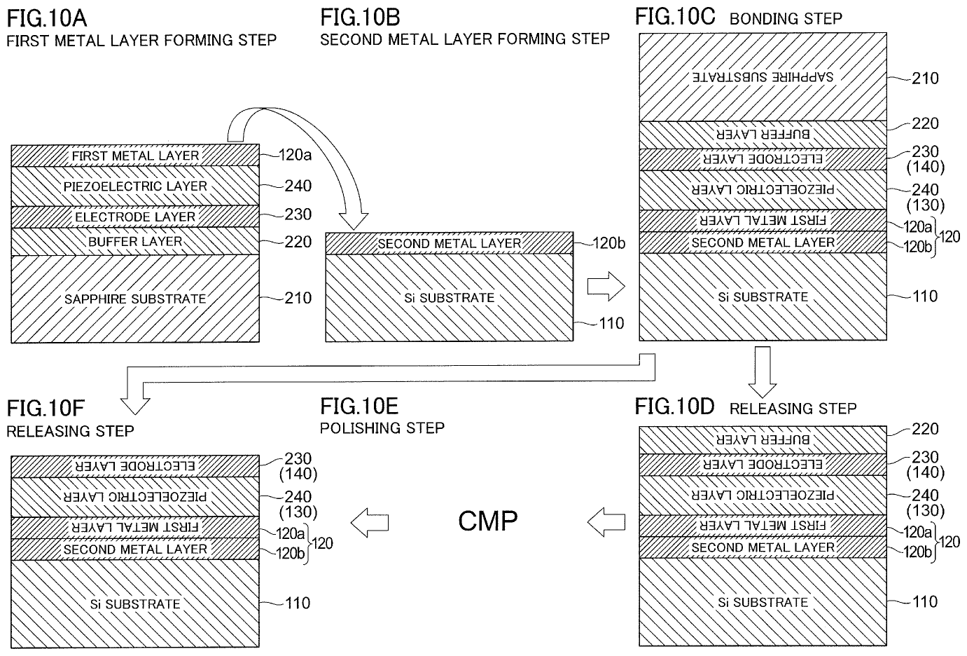

FIGS. 10A to 10F show a method for manufacturing the resonator 100.

First, the laminate 200 is formed by the method described with reference to FIG. 8 (laminate forming step).

Then, as shown in FIG. 10A, a first metal layer is formed on the laminate 200. The first metal layer can be formed by sputtering. The first metal layer forms a part of the lower electrode layer 120 (see FIG. 1). In FIG. 10A, this first metal layer is denoted as a lower electrode layer 120a to indicate that it is a part of the lower electrode layer 120. Hence, this step can be viewed as a first metal layer forming step of forming the first metal layer (lower electrode layer 120a) containing a metal on the laminate 200.

Then, as shown in FIG. 10B, a second metal layer is formed on the substrate 110. Similarly to the first metal layer, the second metal layer can be formed by sputtering. The second metal layer forms a part of the lower electrode layer 120 (see FIG. 1). In FIG. 10B, this second metal layer is denoted as a lower electrode layer 120b to indicate that it is a part of the lower electrode layer 120. Hence, this step can be viewed as a second metal layer forming step of forming the second metal layer on a second substrate (substrate 110) different from the substrate 210 (denoted as “sapphire substrate” in FIG. 10A). As previously described with reference to FIG. 1, the substrate 110, which is an example of the second substrate, is a silicon (Si) single-crystalline substrate (denoted as “Si substrate” in FIG. 10B).

Ruthenium (Ru), gold (Au), silver (Ag), copper (Cu), platinum (Pt), aluminum (Al), molybdenum (Mo), tungsten (W), and the like may be used for the lower electrode layers 120a, 120b.

Then, as shown in FIG. 10C, a top surface of the laminate 200 with the first metal layer (lower electrode layer 120a) formed thereon is bonded to a top surface of the substrate 110 with the second metal layer (lower electrode layer 120b) formed thereon. Hence, this step can be viewed as a bonding step of bonding the first metal layer (lower electrode layer 120a) formed on the laminate 200 to the second metal layer (lower electrode layer 120b) on the second substrate (substrate 110). For example, the bonding of these layers is performed by a joining machine that applies heat and pressure to join them.

As shown in FIG. 10C, this results in a joined body formed by lamination of the substrate 110, the lower electrode layer 120b, the lower electrode layer 120a, the piezoelectric layer 240 (piezoelectric layer 130), the electrode layer 230 (upper electrode layer 140), the buffer layer 220, and the substrate 210. The lower electrode layer 120a and the lower electrode layer 120b can be collectively viewed as the lower electrode layer 120.

Then, the substrate 210 and the buffer layer 220 are released from the laminate 200 (releasing step). For example, the releasing may be performed with pulsed high-density ultraviolet (UV) laser light emitted from a laser lift-off apparatus.

In this step, both of the substrate 210 and the buffer layer 220 may be released at a time as shown in FIG. 10F.

As shown in FIG. 10D, on the other hand, at least a portion of the buffer layer 220 may be left unreleased. In the case of FIG. 10D, the residual buffer layer 220 is removed by chemical mechanical polishing (CMP) shown in FIG. 10E. This results in the state shown in FIG. 10F. In this case, the step includes releasing the substrate 210 and then releasing the buffer layer 220.

The laminate in the state shown in FIG. 10F can be referred to as a released laminate obtained by releasing the piezoelectric layer 240 and the electrode layer 230 from the laminate 200.

Through these steps, the resonator 100 formed by lamination of the substrate 110, the lower electrode layer 120, the piezoelectric layer 130, and the upper electrode layer 140 can be manufactured as shown in FIG. 10F.

The embodiment detailed above provides the buffer layer 220 and the electrode layer 230 with excellent crystallinity. The piezoelectric layer 240 laminated on these layers can also have excellent crystallinity. In other words, the above embodiment provides the single-crystalline buffer layer 220, electrode layer 230, and piezoelectric layer 240.

Ensuring excellent crystallinity of the piezoelectric layer 240 holds promise for manufacturing a resonator or a high-frequency filter that can function as a filter having a high Q value and a wide bandwidth. In other words, while conventional filters have a tradeoff between a high Q value and a wide bandwidth, filters of the present embodiment are expected to achieve both of these characteristics.

Ensuring excellent crystallinity of the piezoelectric layer 240 also leads to fewer grain boundaries and low-loss characteristics. This, in turn, facilitates achieving a high Q value. In addition, the laminate of the present embodiment is epitaxially grown on the substrate 210, which is likely to lead to low-loss characteristics and achieving a high Q value as well. Further, the laminate of the present embodiment has high thermal conductivity and excellent voltage resistance. For this reason, the laminate has good heat dissipating properties and can be used as a filter for base stations with output power of 10 W or more. The laminate can also be expected to have longer life.

In the above example, the resonator 100 has been described as being used for the FBAR-type BAW filter, but this is not limiting. For example, the resonator 100 may be used for a solidly mounted resonator (SMR)-type BAW filter. The SMR-type BAW filter is provided, in a lower portion of the resonator, with an acoustic multilayer (mirror layer) by which elastic waves are reflected. That is, in the case of the SMR-type BAW filter, the substrate 110 is not provided with the cavity 111, and the acoustic multilayer (mirror layer) is deposited between the substrate 110 and the lower electrode layer 120.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A laminate comprising:
a substrate;
an electrode layer disposed on or above the substrate and having a single-crystalline structure containing a metal element;
a buffer layer formed between the substrate and the electrode layer and configured to improve crystal orientation of the electrode layer; and
a piezoelectric layer formed on the electrode layer and made of a piezoelectric body, wherein
each of the buffer layer and the piezoelectric layer has a single-crystalline structure based on a composition of either ScAlN or AlN.

2. The laminate according to claim 1, wherein peaks at 60 degrees intervals are observed by X-ray diffraction in a (11-20) plane of the ScAlN and the AlN.

3. The laminate according to claim 1, wherein one zone axis is observed in an electron diffraction pattern of the ScAlN and the AlN.

4. The laminate according to claim 1, wherein both of the buffer layer and the piezoelectric layer have a same composition.

5. The laminate according to claim 1, wherein when the electrode layer is in a cubic crystal system, a lattice mismatch between the electrode layer and the ScAlN or the AlN is in a range from −25% to 2%.

6. The laminate according to claim 1, wherein the electrode layer has a hexagonal crystal structure.

7. The laminate according to claim 1, wherein an X-ray rocking curve full-width at half-maximum (FWHM) of the piezoelectric layer in a (0002) plane is not more than 2.5°.

8. The laminate according to claim 1, wherein when a composition ScₓAl_{y}N (x+y=1), which represents the AlN or the ScAlN, satisfies a relationship of 0≤x≤0.3, the electrode layer comprises at least one substance selected from Co, Cu, Ru, Pt, Al, Au, Ag, Mo, W, ZrN, and Ti, and when the composition ScₓAl_{y}N (x+y=1) satisfies a relationship of 0.3<x≤0.5, the electrode layer comprises at least one substance selected from Co, Ru, Al, Au, Ag, Mo, W, ZrN, and Ti.

9. The laminate according to claim 1, wherein when the ScAlN is represented by a composition ScₓAl_{y}N (x+y=1), a relationship of 0<x≤0.5 is satisfied.

10. The laminate according to claim 1, wherein the substrate has any composition selected from sapphire, Si, quartz, SrTiO₃, LiTaO₃, LiNbO₃, and SiC.

11. The laminate according to claim 1, wherein the electrode layer has a thickness of from 10 to 1000 nm.

12. The laminate according to claim 1, wherein the buffer layer has a thickness of from 10 to 100 nm.

13. A released laminate obtained by releasing the piezoelectric layer and the electrode layer from the laminate according to claim 1.

14. A method for manufacturing a resonator, the method comprising:
forming a laminate, the laminate including: a substrate; an electrode layer disposed on or above the substrate and having a single-crystalline structure containing a metal element; a buffer layer formed between the substrate and the electrode layer and configured to improve crystal orientation of the electrode layer; and a piezoelectric layer formed on the electrode layer and made of a piezoelectric body, each of the buffer layer and the piezoelectric layer having a single-crystalline structure based on a composition of either ScAlN or AlN;
forming, on the laminate, a first metal layer containing a metal;
forming, on a surface of a second substrate different from the substrate, a second metal layer containing a metal;
bonding the first metal layer formed on the laminate to the second metal layer on the second substrate; and
releasing the substrate and the buffer layer from the laminate.

15. The method for manufacturing a resonator according to claim 14, wherein the releasing the substrate and the buffer layer comprises releasing both of the substrate and the buffer layer at a time.

16. The method for manufacturing a resonator according to claim 14, wherein the releasing the substrate and the buffer layer comprises releasing the substrate and then releasing the buffer layer.
